(19) United States
(12) Patent Application Publication
(10) Pub. No.: US 2025/0219028 A1
(43) Pub. Date: Jul. 3, 2025

(54) DEEP TRENCH CAPACITORS IN MULTI-CORE INTEGRATED CIRCUIT DEVICE PACKAGE SUBSTRATES

(71) Applicant: Intel Corporation, Santa Clara, CA (US)

(72) Inventors: Jeremy Ecton, Gilbert, AZ (US); Bohan Shan, Chandler, AZ (US); Numair Ahmed, Chandler, AZ (US); Nevin Erturk, Atlanta, GA (US); Ziyin Lin, Phoenix, AZ (US); Ryan Carrazzone, Chandler, AZ (US); Hongxia Feng, Chandler, AZ (US); Hiroki Tanaka, Gilbert, AZ (US); Haobo Chen, Chandler, AZ (US); Kyle Arrington, Gilbert, AZ (US); Jose Waimin, Gilbert, AZ (US); Srinivas Pietambaram, Chandler, AZ (US); Gang Duan, Chandler, AZ (US); Dingying Xu, Chandler, AZ (US); Mohit Gupta, Chandler, AZ (US); Brandon Marin, Gilbert, AZ (US); Xiaoying Guo, Chandler, AZ (US); Clay Arrington, Queens Creek, AZ (US)

(73) Assignee: Intel Corporation, Santa Clara, CA (US)

(21) Appl. No.: 18/399,527

(22) Filed: Dec. 28, 2023

(51) Int. Cl. H01L 25/16; H01L 21/48; H01L 23/498

(52) U.S. Cl. CPC H01L 25/16; H01L 21/4857; H01L 21/486; H01L 23/49822

(57) ABSTRACT

An apparatus is provided which comprises: a substrate core comprising a first core layer bonded with a second core layer, one or more redistribution layers on a first substrate core surface, one or more conductive contacts on a second substrate core surface opposite the first substrate core surface, one or more vias through the substrate core, a first circuit component embedded entirely within a cavity in the first core layer, the first circuit component coupled with a first redistribution layers surface, wherein the first circuit component and the first core layer have substantially equivalent heights, and wherein the first circuit component comprises a deep trench capacitor, and one or more integrated circuit devices coupled with a second redistribution layers surface opposite the first redistribution layers surface. Other embodiments are also disclosed and claimed.

### BACKGROUND

Computing platforms, such as desktops, laptops or smart phones, for example, are expected to have increased performance compared with previous iterations. One way that manufacturers of computing platforms can achieve increased performance is by integrating more integrated circuit devices into a single package. Heterogeneous integration refers to the integration of separately manufactured components into an assembly that, in the aggregate, provides enhanced functionality and improved operating characteristics. As more computing cores are integrated into a package, or system on a chip, there arises a need to integrate more power delivery components into the package as well. With increased integration, there can arise issues with warpage, power delivery, and thermal management within device packages. Therefore, there is a need for high performance architectures that address these issues.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a cross-sectional view of an example deep trench capacitor in a multi-core integrated circuit device package substrate, according to some embodiments;

FIGS. 2A-2F illustrate cross-sectional views of example manufacturing steps of forming a deep trench capacitor in a multi-core integrated circuit device package substrate, according to some embodiments;

FIGS. 3A-3F illustrate cross-sectional views of example manufacturing steps of forming a deep trench capacitor in a multi-core integrated circuit device package substrate, according to some embodiments;

FIG. 4 illustrates a cross-sectional view of an example deep trench capacitor in a multi-core integrated circuit device package substrate, according to some embodiments;

FIG. 5 illustrates a flowchart of an example method of forming a deep trench capacitor in a multi-core integrated circuit device package substrate, in accordance with some embodiments; and

FIG. 6 illustrates a smart device or a computer system or a SoC (System-on-Chip) which includes a deep trench capacitor in a multi-core integrated circuit device package substrate, according to some embodiments.

### DETAILED DESCRIPTION

Deep trench capacitors in multi-core integrated circuit device package substrates are generally presented. In this regard, embodiments of the present disclosure enable substrate cores for embedding of thin components that may be prone to shifting or rotating when embedded in conventional substrate cores. One skilled in the art would appreciate that these substrate cores may enable more components, such as power delivery components, to be integrated in a stacked die package. Additionally, the architectures described herein may offer improved thermal management, power delivery, and reliability, and thereby enable enhanced features.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

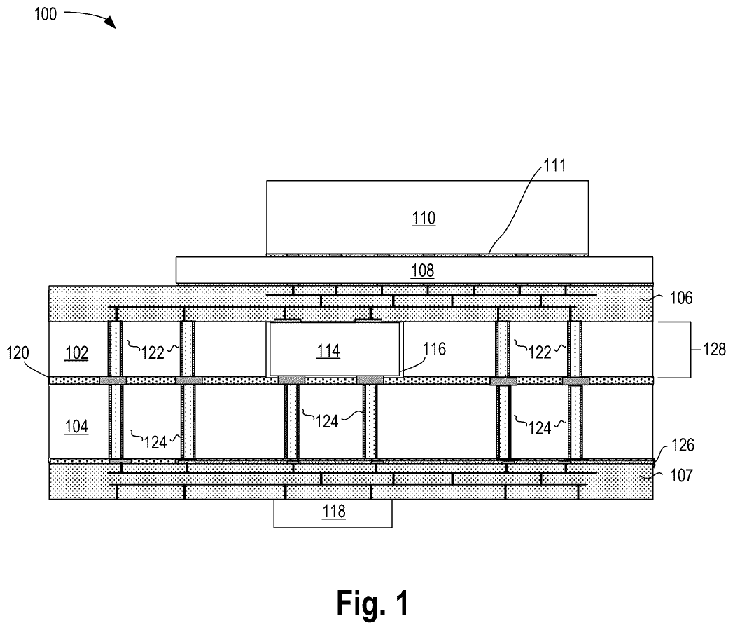

FIG. 1 illustrates a cross-sectional view of an example deep trench capacitor in a multi-core integrated circuit device package substrate, according to some embodiments. As shown, device package 100 includes first substrate core material 102, second substrate core material 104, redistribution layers 106 and 107, integrated circuit device 108, integrated circuit device 110, device interconnect 111, embedded device 114, substrate core cavity 116, device 118, bond layer 120, vias 122, vias 124, interconnect layer 126, and substrate core height 128. In some embodiments, device package 100 may include additional layers and integrate additional components.

In some embodiments, first substrate core material 102 may be a glass or organic dielectric material. In some embodiments, first substrate core material 102 may be a silicate (for example silicon dioxide-based) glass that may be tempered or treated. In some embodiments, first substrate core material 102 is a non-crystalline amorphous solid. In some embodiments, first substrate core material 102 may be designed to be thin and damage-resistant. In some embodiments, first substrate core material 102 is pre-formed and not deposited in-situ using a traditional deposition technique, such as atomic layer deposition or chemical vapor deposition, for example. In some embodiments, first substrate core material 102 is made by fusing liquid sand with soda ash (sodium carbonate), limestone (calcium carbonate), and/or other ingredients and cooling rapidly. In some embodiments, first substrate core material 102 may contain boron oxide for improved thermal resistance. In some embodiments, first substrate core material 102 may contain lead oxide for improved ease of cutting. In some embodiments, first substrate core material 102 may contain a sandwich or laminate of multiple layers of glass that are plastic bonded together. In some embodiments, first substrate core material 102 is transparent or translucent. First substrate core material 102 may have an inherently low surface roughness and a high temperature tolerance, allowing for uniform thin film depositions that require annealing. In some embodiments, first substrate core material 102 may have a relatively low coefficient of thermal expansion (CTE). In some embodiments, first substrate core material 102 may also contain ceramic material. In some embodiments, the thermal expansion of first substrate core material 102 is controlled by firing to create crystalline species that will influence the overall expansion of first substrate core material 102 in the desired direction. For example, first substrate core material 102 may include crystalline additives that tend to thermally expand longitudinally, as opposed to laterally. In some embodiments, the formulation of first substrate core material 102 employs materials delivering particles of the desired expansion to the matrix. In some embodiments, first substrate core material 102 may include a glaze (not shown) that may have the effect of reducing thermal expansion. In some embodiments, second substrate core material 104 may be a same material, such as glass, for example, as first substrate core material 102.

Substrate core cavity 116 may be formed through first substrate core material 102 by any known method, including, but not limited to, chemical or mechanical etching. In some embodiments, first substrate core material 102 may be formed about a template that forms substrate core cavity 116.

In some embodiments, embedded device 114 may represent a component or integrated circuit device. In some embodiments, embedded device 114 may a be circuit component such as a capacitor or inductor. In some embodiments, embedded device 114 is a discrete deep trench capacitor that is fabricated using wafer level processes.

In some embodiments, device 118 may be a memory device, such as a high bandwidth memory (HBM). In some embodiments, device 118 may be an intelligent power device (IPD). In other embodiments, device 118 may be a photonic integrated circuit (PIC) or an embedded passive component (EPC). While shown as being a single device, device 118 may be implemented as a stack of multiple homogeneous or heterogeneous devices.

Substrate core height 128 may be designed to match a height of embedded device 114 to prevent shifting and rotating of embedded device 114. In some embodiments, where embedded device 114 is a discrete deep trench capacitor, substrate core height 128 may be around 600 micrometers. In some embodiments, embedded device 114 may have a height within 95 to 105 percent of substrate core height 128. Second substrate core 104 may have a height designed to add with substrate core height 128 to provide a cumulative height necessary to provide sufficient mechanical support. In some embodiments, second substrate core 104 has a greater height than substrate core height 128, while in other embodiments second substrate core 104 has a lesser height than substrate core height 128.

In some embodiments, bond layer 120 may be present between first substrate core material 102 and second substrate core material 104. In some embodiments, bond layer 120 may be an adhesive material. In some embodiments, bond layer 120 may be an underfill material surrounding solder joints. In some embodiments, bond layer 120 may be a dielectric layer that is laser treated. In some embodiments, bond layer 120 may be microscopic changes to first substrate core material 102 and/or second substrate core material 104 as the result of thermal and/or pressure bonding.

Vias 122 and/or 124 may be drilled through first substrate core material 102 and second substrate core material 104, respectively, by any known method, including, for example, laser drilling and plating, to provide electrical pathways from redistribution layers 106 or embedded device 114 to interconnect layer 126. Vias 122 and/or 124 may also be lined and/or filled with additional dielectric material to provide electrical insulation. In some embodiments, vias 122 and 124 may be soldered together as part of a process of bonding first substrate core material 102 with second substrate core material 104.

Redistribution layers 106 and 107 may be formed over opposite sides of first substrate core material 102 and second substrate core material 104, respectively. In some embodiments, redistribution layers 106 may include multiple layers of interlayer dielectric, such as organic dielectric, for example, along with metal wires to route contacts of vias 122 and embedded device 114 to integrated circuit devices 108 and 110. In some embodiments, redistribution layers 106 may fan-in a contact pitch from first substrate core material 102 to integrated circuit device 108.

As shown, an integrated circuit device stack may include integrated circuit devices 108 and 110, which are bonded with redistribution layers 106 through device interconnect 111. In some embodiments, device interconnect 111 may represent traditional solder bonding. In other embodiments, device interconnect 111 may represent hybrid bonding. In some embodiments, device interconnect 111 may represent a direct chip to chip interconnect using high bandwidth interconnect (HBI). In some embodiments, integrated circuit devices 108 and/or 110 may represent controllers, processors, or system-on-a-chip (SOCs), such as multi-core processors, for example. In some embodiments, integrated circuit devices 108 and 110 may be surrounded by an epoxy underfill (not shown).

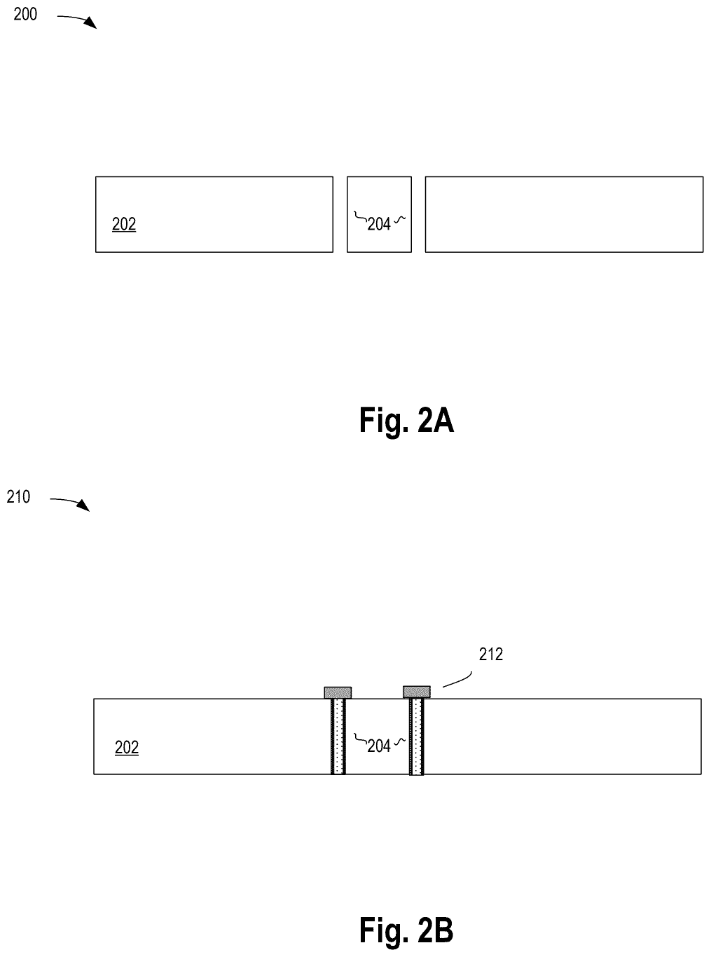

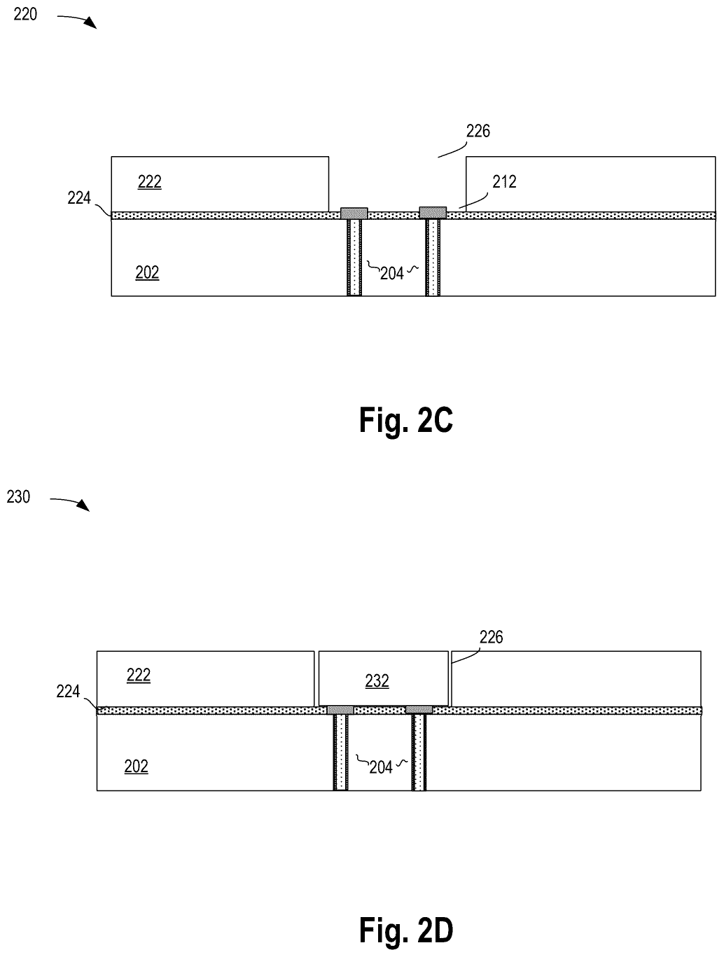

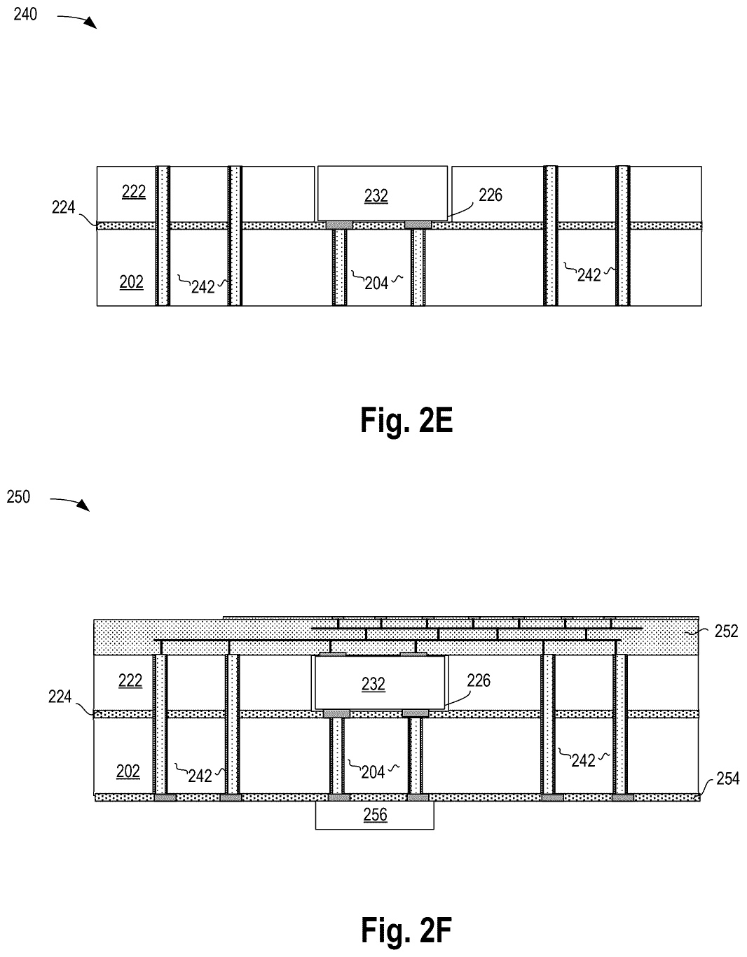

FIGS. 2A-2F illustrate cross-sectional views of example manufacturing steps of forming a deep trench capacitor in a multi-core integrated circuit device package substrate, according to some embodiments. As shown in FIG. 2A, assembly 200 includes first substrate core material 202, and vias 204. In some embodiments, first substrate core material 202 may be a preformed piece of glass including vias 204 and any of the properties mentioned previously, for example in reference to FIG. 1. In some embodiments, first substrate core material 202 may be organic dielectric material. In some embodiments, vias 204 are formed by laser drilling through first substrate core material 202.

FIG. 2B shows assembly 210, which may include contacts 212 over plated vias 204. In some embodiments, contacts 212 may be copper contacts or solder bumps. In some embodiments, vias 204 may also be lined and/or filled with additional dielectric material to provide electrical insulation.

As shown in FIG. 2C, assembly 220 includes second substrate core material 222, bond layer 224, and substrate core cavity 226. In some embodiments, second substrate core material 222 may be a preformed piece of glass including substrate core cavity 226 and any of the properties mentioned previously, for example in reference to FIG. 1. In some embodiments, second substrate core material 222 may be organic dielectric material. In some embodiments, substrate core cavity 226 is formed separately by removing a portion of second substrate core material 222. In some embodiments, second substrate core material 222 may be a same or similar material as first substrate core material 202. While shown as including one substrate core cavity 226, any number of substrate core cavities 226 may be present. In some embodiments, a height of second substrate core material 222 is selected based on the height of one or more devices to be embedded within substrate core cavity 226. While shown as being present before a device is placed in substrate core cavity 226, in some embodiments, bonding layer 224 may be an underfill material that is added in a later step.

Turning now to FIG. 2D, assembly 230 may include device 232 within substrate core cavity 226. Device 232 may represent any type of device, including, but not limited to, deep trench capacitor, inductor, high bandwidth memory (HBM), intelligent power device (IPD), photonic integrated circuit (PIC), and embedded passive components (EPC). In some embodiments, adhesive or other filler may be added to secure device 232 within substrate core cavity 226.

FIG. 2E shows assembly 240, which may include vias 242 formed through first substrate core material 202 and second substrate core material 222. In some embodiments, vias 242 may include conductive material, such as metal, with additional insulative material surrounding (and/or surrounded by) the conductive material. Vias 242 may be formed by laser drilling or any other known method through the combined first substrate core material 202 and second substrate core material 222.

As shown in FIG. 2F, assembly 250 may include redistribution layers 252 over second substrate core material 222 and device 232, thereby embedding device 232 within substrate core cavity 226. In some embodiments, redistribution layers 252 may include multiple layers of metal routing, such as copper, and interlayer dielectric to insulate and cover the metal. In some embodiments, redistribution layers 252 may include a dielectric material deposited by any known technique, including, but not limited to, atomic layer deposition or chemical vapor deposition. In some embodiments, redistribution layers 252 may fan-in a wider contact pitch below to a narrower contact pitch above redistribution layers 252. In some embodiments, device 256 may be coupled with interconnect layer 254 and communicatively coupled with device 232 through vias 204. Device 256 may represent any type of active or passive device including, but not limited to, deep trench capacitor, inductor, high bandwidth memory (HBM), intelligent power device (IPD), photonic integrated circuit (PIC), and embedded passive components (EPC).

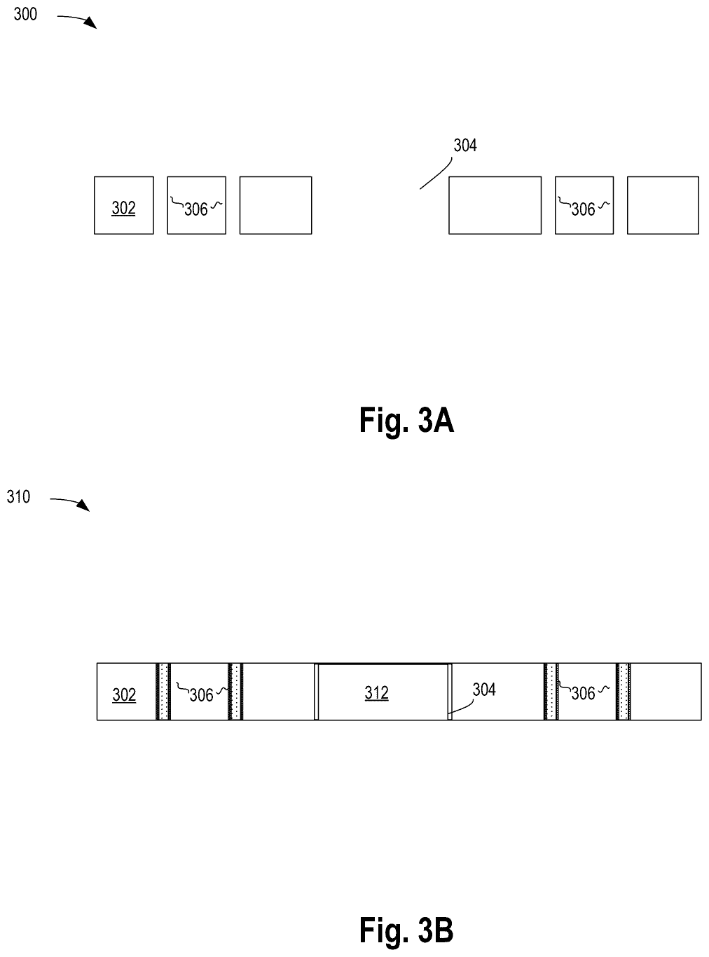

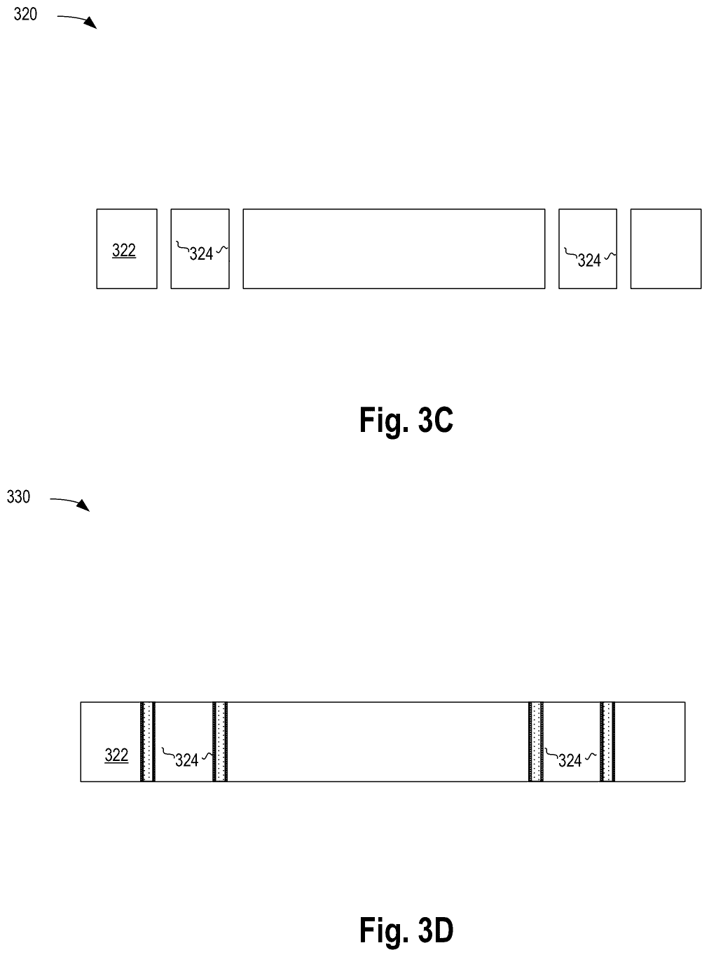

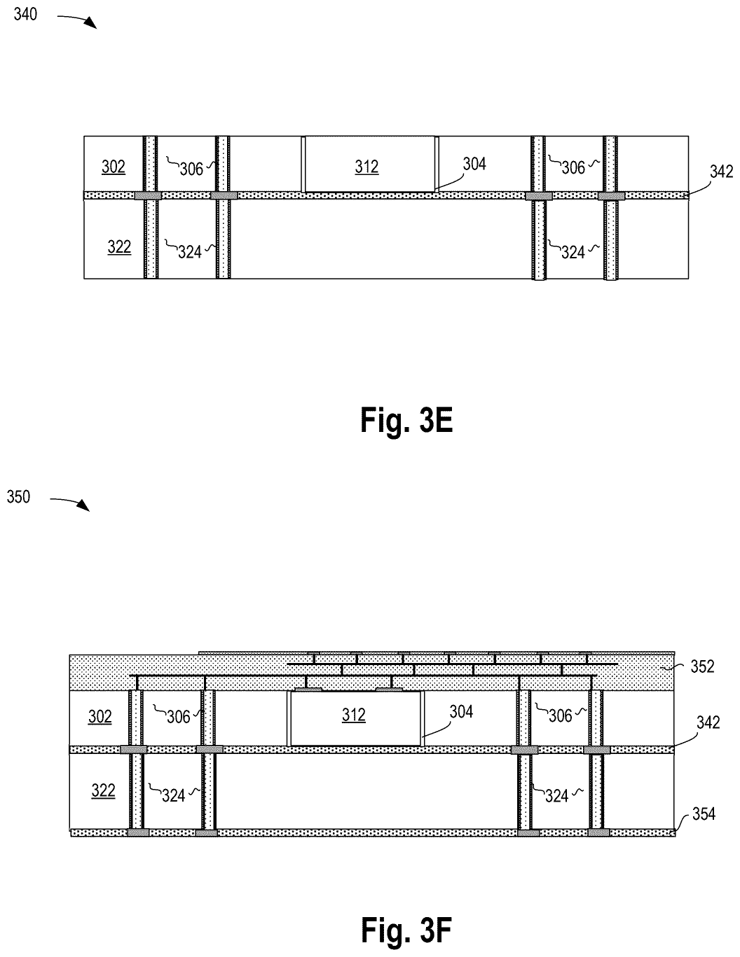

FIGS. 3A-3F illustrate cross-sectional views of example manufacturing steps of forming a deep trench capacitor in a multi-core integrated circuit device package substrate, according to some embodiments. As shown in FIG. 3A, assembly 300 includes first substrate core material 302, substrate core cavity 304, and vias 306. In some embodiments, first substrate core material 302 may be a preformed piece of glass including substrate core cavity 304 and any of the properties mentioned previously, for example in reference to FIG. 1. In some embodiments, first substrate core material 302 may be organic dielectric material. In some embodiments, substrate core cavity 304 is formed separately by removing a portion of first substrate core material 302. While shown as including square sidewalls, substrate core cavity 304 may include angled sidewalls. While shown as including one substrate core cavity 304, any number of substrate core cavities 304 may be present. In some embodiments, a height of first substrate core material 302 is selected based on the height of one or more devices to be embedded within substrate core cavity 304.

FIG. 3B shows assembly 310, which may include device 312 within substrate core cavity 304. Device 312 may represent any type of device, including, but not limited to, deep trench capacitor, inductor, high bandwidth memory (HBM), intelligent power device (IPD), photonic integrated circuit (PIC), and embedded passive components (EPC). In some embodiments, adhesive or other filler may be added to secure device 312 within substrate core cavity 304.

As shown in FIG. 3C, assembly 320 includes second substrate core material 322, and vias 324. In some embodiments, second substrate core material 322 may be a preformed piece of glass including vias 324 and any of the properties mentioned previously, for example in reference to FIG. 1. In some embodiments, second substrate core material 322 may be organic dielectric material.

Turning now to FIG. 3D, assembly 330 may include plating of vias 324. In some embodiments, vias 324 may include conductive material, such as metal, with additional insulative material surrounding (and/or surrounded by) the conductive material. Vias 324 may be formed by laser drilling or any other known method through second substrate core material 322.

FIG. 3E shows assembly 340, which may include first substrate core material 302 coupled with second substrate core material 322 through bonding layer 342. As shown, vias 306 may be soldered with vias 324. In some embodiments, bonding layer 342 may include adhesive, laser-treated, or heat-treated dielectric, for example.

As shown in FIG. 3F, assembly 350 may include redistribution layers 352 over first substrate core material 302 and device 312, thereby embedding device 312 within substrate core cavity 304. In some embodiments, redistribution layers 352 may include multiple layers of metal routing, such as copper, and interlayer dielectric to insulate and cover the metal. In some embodiments, redistribution layers 352 may include a dielectric material deposited by any known technique, including, but not limited to, atomic layer deposition or chemical vapor deposition. In some embodiments, redistribution layers 352 may fan-in a wider contact pitch below from interconnect layer 354 to a narrower contact pitch above redistribution layers 352.

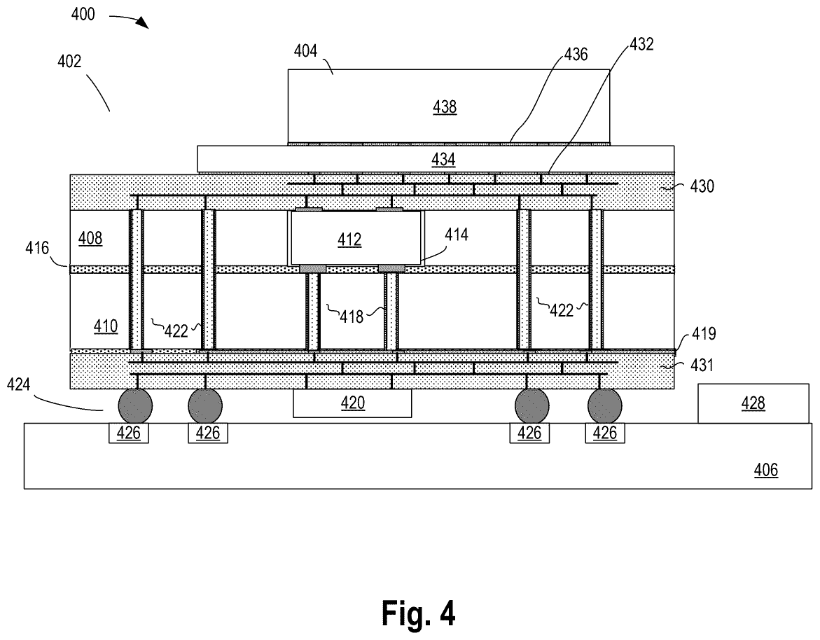

FIG. 4 illustrates a cross-sectional view of an example deep trench capacitor in a multi-core integrated circuit device package substrate, according to some embodiments. As shown, assembly 400 includes device package 402, integrated circuit device stack 404, system board 406, first substrate core 408, second substrate core 410, deep trench capacitor 412, substrate core cavity 414, bond layer 416, vias 418, device package surface 419, device 420, full-height vias 422, solder balls 424, board pads 426, board component 428, redistribution layers 430 and 431, interconnect 432, bottom integrated circuit device 434, device interconnect 436, and top integrated circuit device 438.

Device package 402 may incorporate elements previously discussed in reference to prior figures. For example, device package 402 may have properties discussed in reference to FIGS. 1, 2A-2F, or 3A-3F. As shown, device package 402 may include integrated circuit device stack 404 with top integrated circuit device 438 stacked on bottom integrated circuit device 434, however, device package may in other devices in other configurations, for example, multiple integrated circuit devices coupled through an embedded multi-die interconnect bridge.

In some embodiments, solder balls 424 may be formed on device package surface 419, thereby allowing device package 402 to be soldered to system board 406 through board pads 426. System board 406 may also incorporate board component 428, which may represent any type of active or passive system components, such as a power supply, memory devices, voltage regulators, I/O interfaces, etc.

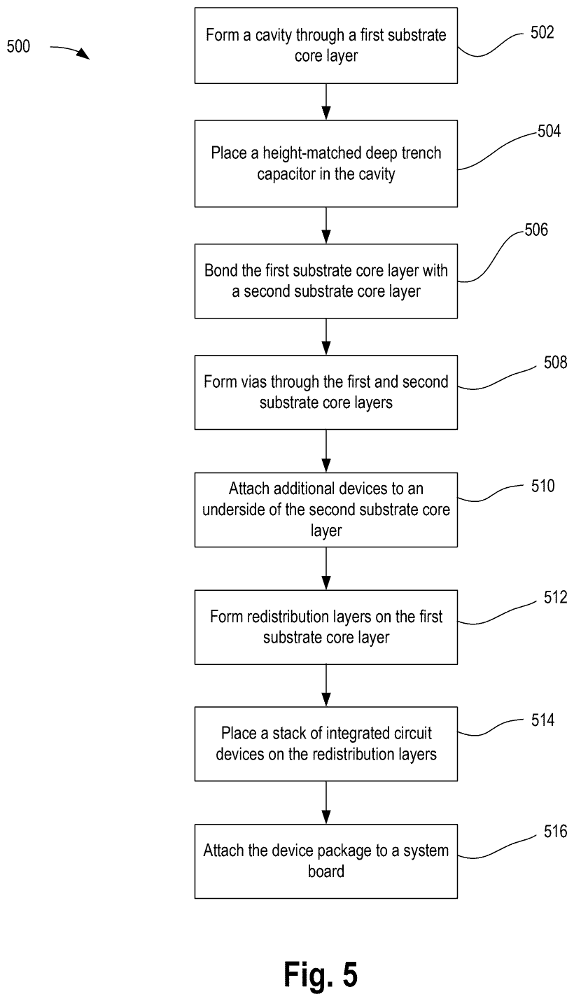

FIG. 5 illustrates a flowchart of an example method of forming a deep trench capacitor in a multi-core integrated circuit device package substrate, in accordance with some embodiments. Although the blocks in the flowchart with reference to FIG. 5 are shown in a particular order, the order of the actions can be modified. Thus, the illustrated embodiments can be performed in a different order, and some actions/blocks may be performed in parallel. Some of the blocks and/or operations listed in FIG. 5 are optional in accordance with certain embodiments. The numbering of the blocks presented is for the sake of clarity and is not intended to prescribe an order of operations in which the various blocks must occur. Additionally, operations from the various flows may be utilized in a variety of combinations.

Method 500 begins with forming (502) a cavity through a first substrate core material. In some embodiments, such as assembly 300, substrate core cavity 304 may be formed through first substrate core material 302. Next, a height-matched deep trench capacitor is placed (504) in the cavity. In some embodiments, such as assembly 310, device 312 may be placed in substrate core cavity 304.

Then, the first substrate core layer may be bonded (506) with a second substrate core layer. In some embodiments, such as assembly 340, bonding layer 342 may bond first substrate core material 302 with second substrate core material 322. Next, vias may be formed (508) through the coupled substrate core materials. In some embodiments, such as assembly 240, vias 242 may be formed through both the first and the second substrate core materials.

The method continues, in some embodiments, with attaching (510) additional devices to an underside of the second substrate core layer. In some embodiments, such as assembly 250, device 256 may be attached to couple with device 232. Next, redistribution layers may be formed (512) over the coupled substrate core materials. In some embodiments, such as assembly 350, redistribution layers 352 may be formed over first substrate core material 302.

Next, a stack of integrated circuit devices may be placed (514) on the redistribution layers. In some embodiments, such as device package 100, integrated circuit devices 108 and 110 may be stacked on redistribution layers 106. Finally, the device package may be attached (516) to a system board. In some embodiments, such as assembly 400, device package 402 may be attached to system board 406.

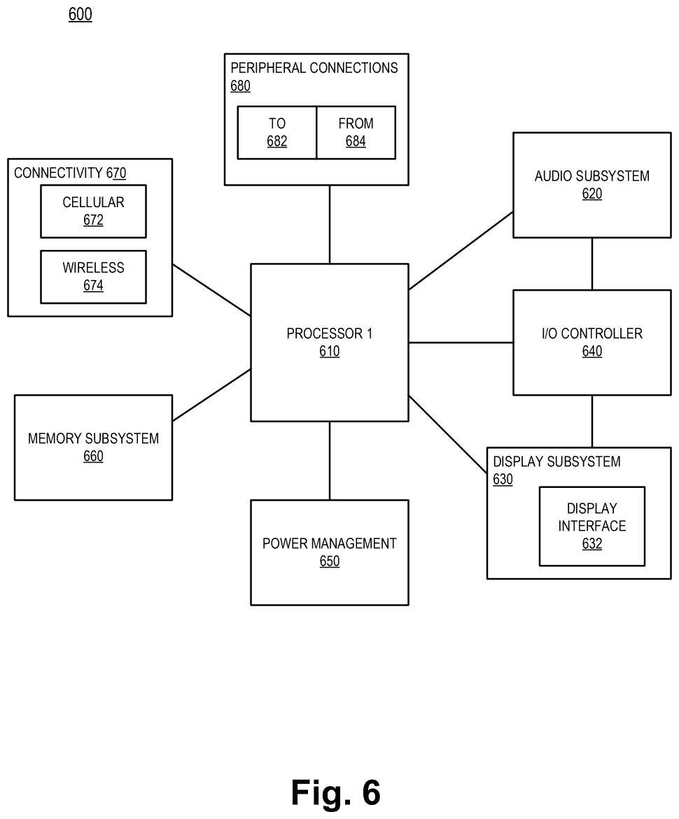

FIG. 6 illustrates a smart device or a computer system or a SoC (System-on-Chip) which includes a deep trench capacitor in a multi-core integrated circuit device package substrate, according to some embodiments. In some embodiments, computing device 600 represents a mobile computing device, such as a computing tablet, a mobile phone or smart-phone, a wireless-enabled e-reader, or other wireless mobile device. It will be understood that certain components are shown generally, and not all components of such a device are shown in computing device 600. In some embodiments, one or more components of computing device 600, for example processor 610 or I/O controller 640, include a deep trench capacitor in a multi-core integrated circuit device package substrate as described above.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, etc., may be used without departing from the scope of the disclosure.

In some embodiments, computing device 600 includes a first processor 610. The various embodiments of the present disclosure may also comprise a network interface within 670 such as a wireless interface so that a system embodiment may be incorporated into a wireless device, for example, cell phone or personal digital assistant.

In one embodiment, processor 610 can include one or more physical devices, such as microprocessors, application processors, microcontrollers, programmable logic devices, or other processing means. The processing operations performed by processor 610 include the execution of an operating platform or operating system on which applications and/or device functions are executed. The processing operations include operations related to I/O (input/output) with a human user or with other devices, operations related to power management, and/or operations related to connecting the computing device 600 to another device. The processing operations may also include operations related to audio I/O and/or display I/O.

In one embodiment, computing device 600 includes audio subsystem 620, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 600, or connected to the computing device 600. In one embodiment, a user interacts with the computing device 600 by providing audio commands that are received and processed by processor 610.

Display subsystem 630 represents hardware (e.g., display devices) and software (e.g., drivers) components that provide a visual and/or tactile display for a user to interact with the computing device 600. Display subsystem 630 includes display interface 632, which includes the particular screen or hardware device used to provide a display to a user. In one embodiment, display interface 632 includes logic separate from processor 610 to perform at least some processing related to the display. In one embodiment, display subsystem 630 includes a touch screen (or touch pad) device that provides both output and input to a user.

I/O controller 640 represents hardware devices and software components related to interaction with a user. I/O controller 640 is operable to manage hardware that is part of audio subsystem 620 and/or display subsystem 630. Additionally, I/O controller 640 illustrates a connection point for additional devices that connect to computing device 600 through which a user might interact with the system. For example, devices that can be attached to the computing device 600 might include microphone devices, speaker or stereo systems, video systems or other display devices, keyboard or keypad devices, or other I/O devices for use with specific applications such as card readers or other devices.

As mentioned above, I/O controller 640 can interact with audio subsystem 620 and/or display subsystem 630. For example, input through a microphone or other audio device can provide input or commands for one or more applications or functions of the computing device 600. Additionally, audio output can be provided instead of, or in addition to display output. In another example, if display subsystem 630 includes a touch screen, the display device also acts as an input device, which can be at least partially managed by I/O controller 640. There can also be additional buttons or switches on the computing device 600 to provide I/O functions managed by I/O controller 640.

In one embodiment, I/O controller 640 manages devices such as accelerometers, cameras, light sensors or other environmental sensors, or other hardware that can be included in the computing device 600. The input can be part of direct user interaction, as well as providing environmental input to the system to influence its operations (such as filtering for noise, adjusting displays for brightness detection, applying a flash for a camera, or other features).

In one embodiment, computing device 600 includes power management 650 that manages battery power usage, charging of the battery, and features related to power saving operation. Memory subsystem 660 includes memory devices for storing information in computing device 600. Memory can include nonvolatile (state does not change if power to the memory device is interrupted) and/or volatile (state is indeterminate if power to the memory device is interrupted) memory devices. Memory subsystem 660 can store application data, user data, music, photos, documents, or other data, as well as system data (whether long-term or temporary) related to the execution of the applications and functions of the computing device 600.

Elements of embodiments are also provided as a machine-readable medium (e.g., memory 660) for storing the computer-executable instructions. The machine-readable medium (e.g., memory 660) may include, but is not limited to, flash memory, optical disks, CD-ROMs, DVD ROMs, RAMS, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 670 includes hardware devices (e.g., wireless and/or wired connectors and communication hardware) and software components (e.g., drivers, protocol stacks) to enable the computing device 600 to communicate with external devices. The computing device 600 could be separate devices, such as other computing devices, wireless access points or base stations, as well as peripherals such as headsets, printers, or other devices.

Connectivity 670 can include multiple different types of connectivity. To generalize, the computing device 600 is illustrated with cellular connectivity 672 and wireless connectivity 674. Cellular connectivity 672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 674 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 680 include hardware interfaces and connectors, as well as software components (e.g., drivers, protocol stacks) to make peripheral connections. It will be understood that the computing device 600 could both be a peripheral device (“to” 682) to other computing devices, as well as have peripheral devices (“from” 684) connected to it. The computing device 600 commonly has a “docking” connector to connect to other computing devices for purposes such as managing (e.g., downloading and/or uploading, changing, synchronizing) content on computing device 600. Additionally, a docking connector can allow computing device 600 to connect to certain peripherals that allow the computing device 600 to control content output, for example, to audiovisual or other systems.

In addition to a proprietary docking connector or other proprietary connection hardware, the computing device 600 can make peripheral connections 680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. An apparatus comprising:
a substrate core comprising a first core layer bonded with a second core layer;
one or more redistribution layers on a first substrate core surface;
one or more conductive contacts on a second substrate core surface opposite the first substrate core surface;
one or more vias through the substrate core coupling at least one of the conductive contacts on the second substrate core surface with a first redistribution layers surface on the first substrate core surface;
a first circuit component embedded entirely within a cavity in the first core layer, the first circuit component coupled with a first redistribution layers surface, wherein the first circuit component and the first core layer have substantially equivalent heights, and wherein the first circuit component comprises a deep trench capacitor; and
one or more integrated circuit devices coupled with a second redistribution layers surface opposite the first redistribution layers surface.

2. The apparatus of claim 1, wherein the first core layer comprises a height of about 600 micrometers.

3. The apparatus of claim 1, wherein the first core layer and the second core layer comprise glass.

4. The apparatus of claim 1, further comprising adhesive coupling the first core layer with the second core layer.

5. The apparatus of claim 1, wherein the one or more vias comprise preformed vias in the first and second core layers that are soldered together.

6. The apparatus of claim 1, further comprising one or more vias through the second core layer coupling the first circuit component with a second circuit component on the second substrate core surface.

7. The apparatus of claim 1, wherein the second core layer has a greater thickness than the first core layer.

8. A system comprising:
a host board;
an integrated circuit device package, the integrated circuit device package comprising:
a substrate core comprising a first core layer bonded with a second core layer, wherein the first core layer comprises a height of about 600 micrometers;
one or more redistribution layers on a first substrate core surface;
one or more conductive contacts on a second substrate core surface opposite the first substrate core surface;
one or more vias through the substrate core coupling at least one of the conductive contacts on the second substrate core surface with a first redistribution layers surface on the first substrate core surface;
a first circuit component embedded entirely within a cavity in the first core layer, the first circuit component coupled with a first redistribution layers surface, wherein a first circuit component height is within 95 to 105 percent of a first core layer height, and wherein the first circuit component comprises a deep trench capacitor; and
one or more integrated circuit devices coupled with a second redistribution layers surface opposite the first redistribution layers surface; and
a power supply to provide power to the integrated circuit device package through the host board.

9. The system of claim 8, wherein the one or more vias comprise preformed vias in the first and second core layers that are soldered together.

10. The system of claim 8, wherein the first core layer comprises glass.

11. The system of claim 8, wherein the second core layer comprises organic dielectric.

12. The system of claim 8, further comprising one or more vias through the second core layer coupling the first circuit component with a second circuit component on the second substrate core surface.

13. The system of claim 8, further comprising adhesive coupling the first core layer with the second core layer.

14. The system of claim 8, wherein the second core layer has a lesser thickness than the first core layer.

15. A method comprising:
forming a cavity through a first substrate core layer;
placing a deep trench capacitor in the cavity, wherein the deep trench capacitor and the first substrate core layer have substantially matching heights;
bonding the first substrate core layer with a second substrate core layer;
forming vias through the first and second substrate core layers; and
forming redistribution layers on the deep trench capacitor and a surface of the first substrate core layer.

16. The method of claim 15, wherein bonding the first substrate core layer with the second substrate core layer comprises soldering vias in the first substrate core layer with vias in the second substrate core layer.

17. The method of claim 15, wherein coupling the first substrate core layer with the second substrate core layer comprises applying adhesive between the first and second substrate core layers.

18. The method of claim 15, wherein coupling the first substrate core layer with the second substrate core layer comprises coupling the deep trench capacitor with the second substrate core layer.

19. The method of claim 15, further comprising coupling a circuit device with the second substrate core layer.

20. The method of claim 19, further comprising forming one or more vias through the second substrate core layer coupling the deep trench capacitor with the circuit device.
